(19) United States
(12) Patent Application Publication
(10) Pub. No.: US 2026/0178793 A1
(43) Pub. Date: Jun. 25, 2026

(54) METHOD FOR A COMPUTER-ASSISTED CHECK OF AN INSTALLATION ELEMENT FOR AN INSTALLATION ENVIRONMENT

(71) Applicant: Murrelektronik GmbH, Oppenweiler (DE)

(72) Inventors: Sebastian Pfestorf, Backnang (DE); Paul Zeller, Flein (DE)

(21) Appl. No.: 19/127,210

(22) PCT Filed: Oct. 31, 2023
(86) PCT No.: PCT/EP2023/080323

§ 371 Date: May 5, 2025

(30) Foreign Application Priority Data
Nov. 7, 2022 (EP) 22205830.7

(51) Int. Cl. G06F 30/18

(52) U.S. Cl. CPC G06F 30/18

(57) ABSTRACT

The invention relates to a method (100) for a computer-aided verification of an installation element (10) for an installation environment, wherein the method (100) comprises the following steps:
Verifying (101) a suitability of the installation element (10) for installation in the installation environment;
Generating (102) at least one installation information based on a result of the verification (101) to assist a user in the installation; and
Initiating (103) an output of the generated at least one installation information for the user.

### TECHNICAL AREA

The present invention relates generally to the field of planning and assembly of machines such as automation systems and, in particular, to a computer-aided installation of spatially decentralized electrical components of a machine.

### BACKGROUND

The complexity and variety of automation systems that need to be developed, planned, installed, maintained and repaired is increasing. In all phases of the life cycle of such a plant, such as development/planning, production, commissioning, operation and maintenance, simple and efficient support for an installer or planner in the context of electrical installation projects is becoming more important.

During installation, it may happen that the properties of a component used do not match the requirements of the environment. For example, the requirements on site for a plant may differ from the requirements assumed during planning. It then depends on the experience and expertise of an installer whether such deviations are correctly assessed and how the suitability of the component to be installed is judged for further use. This type of verification is therefore subject to a high probability of error with regard to the assessment of product and environmental properties, which may later lead to plant failures.

It is therefore a task of the present invention to provide a computer-aided method and system to enable installation of parts and electrical components while at least partially eliminating the disadvantages described above.

### SUMMARY OF THE INVENTION

The above task is solved by a method, a computer program and an apparatus for data processing according to the independent claims. Further features and details of the invention are shown in the respective subclaims, the description and the drawings.

The object of the invention is in particular a method for a computer-aided verification of an installation element, in particular a component and/or cable and/or plug connection, for an installation environment, preferably in an installation of spatially decentralized, electrical components of a machine, in particular a plant.

The machine may be designed as at least one of the following machines:
An automation system,
A production plant,
A logistics facility,
A production line,
A machining center,
An industrial robot,
A manufacturing facility,
An aggregate,
An electrical appliance.

In particular, the machine may be designed as a machine with a modular character or also as a mobile or movable machine, in which individual parts of the machine are installed modularly in accordance with an installation specification. This installation is at least partially carried out manually by a user such as a worker.

The electrical components may be connection modules that enable decentralized and modular connection of installation elements. Decentralized may refer to the fact that the connection modules at least partially replace a central control cabinet in that the connection modules only provide part of the connections for the machine, but enable these connections to be made decentrally in the field. In the case of a central topology, e.g. a centralized control cabinet concept, this is referred to in particular as a point-to-point connection, i.e. the starting point, the connection and the end point are clearly defined. In contrast, in decentralized applications it is possible, or may even often be necessary, to arrange or connect several components between the starting point and the end point. In this case, we may speak of a module-module or module-hub-point connection, for example. In principle, the following components may be provided in a machine, for example: Devices such as actuators and/or sensors, the connection modules, installation elements, e.g. for cabling.

The method according to the invention may comprise the following steps, which are preferably carried out one after the other or in any order, wherein the steps may also be carried out automatically and/or repeatedly:
Verifying a suitability of the installation element for an installation in the installation environment, preferably based on a compatibility assessment of at least one property of the installation element in relation to at least one property of the installation environment, in particular a temperature and/or humidity and/or electrical voltage and/or acceleration;
Generating at least one installation information based on a result of the verification to assist a user with the installation; and
Initiating an output of the generated at least one installation information for the user.

The method thus enables simpler, faster and error-free installation and may significantly support a user when installing the machine and improve the quality of the process. Furthermore, a significant reduction in time-consuming verifications by qualified specialist personnel may be made possible. Furthermore, the method has the advantage of ensuring a more efficient and effective use of available installation elements such as cables and/or components during installation. In addition, a significant improvement in the service life of the individual installation elements is made possible in an advantageous manner. Furthermore, the method significantly simplifies the more flexible use of manpower, as no high technical qualification requirements are necessary to carry out the installation.

In this way, a support system for installation, in particular for cabling, may be provided during installation with regard to a suitability of an installation element for the intended use, in which data processing apparatus may carry out the method steps in an automated manner. The data processing apparatus, in particular a data processing apparatus according to the invention, may advantageously communicate with individual components and thus enable the output of the installation information. For this purpose, the data processing apparatus may have at least one interface for communication.

For example, a user may be an installer and/or plant mechanic and/or electrician and/or worker and/or planner and/or mechanical designer or developer and/or electrical designer or developer and/or PLC programmer and/or commissioning engineer and/or maintenance engineer and/or machine operator. It is possible for the user to use the method according to the invention by providing the method to the user via a computer. For this purpose, a computer program may be executed at least partially by the computer and/or another computer in order to perform the method steps according to the invention.

Several installation elements may be provided for the installation of the machine. These installation elements may each be assigned an identifier by which the installation elements may be uniquely identified. The identifier may be information that may be processed digitally, for example. The respective installation element may comprise the identifier in that a physical means for identification is provided and/or attached to the installation element. The installation elements may be, for example, cables or components that are a functional part of the machine. The identifier advantageously comprises a unique and, in particular, unambiguous labeling. This makes it possible to uniquely identify the installation element in connection with the machine and/or other machines and/or the installation of the machine using the identifier. One or more pieces of information about the installation element may be assigned to the identifier. The one or more pieces of information may include at least one of the following: at least one status information, the output installation information, an identifier of the identified component, at least one of the documentation specifications described in more detail below, such as component type, machine type, system type, user, connection point designation, time stamp date and time, installation duration, address in a bus system, equipment labeling, cable length, port assignment, properties of the open cable, cable length, temperature, humidity, current project status during installation, deviation from plan and reason. A digital storage of the at least one information assigned to the identifier thus makes it possible to create a digital twin of the installation element.

Preferably, the installation element may comprise a cable and/or a component, wherein the cable may have at least or exactly one plug connection, and may preferably be assembled on one side, i.e. has a female or male plug on one side and an open end on the other side. Alternatively, the cable may also be assembled on two sides, i.e. the cable has a female or male connector on each side.

It may further be possible that the at least one installation information comprises an installation instruction to assist the user with the installation, wherein preferably initiating the output comprises at least one of the following steps:
Initiating an output of the installation instruction as an indication of a connection point of an electrical component for a connection of the installation element and/or an indication of suitability of the installation element, preferably as an indication to the user that the installation element is suitable for use in the installation environment;
Initiating a visual output of the installation instruction, preferably by a graphical user interface and/or by augmented reality and/or by a signaling device of the electrical component;
Initiating an acoustic output, in particular a voice output, of the installation instruction. This enables the user to be informed directly by the installation instruction whether the installation element is suitable for use in the installation environment and in what manner an installation is to be carried out. The user interface may be a graphical user interface that is displayed on a screen, preferably of a computer. The computer may be, for example, a portable computer such as a laptop or tablet.

The display by means of augmented reality may be achieved, for example, by using VR (virtual reality) glasses by a user to display additional information and/or by recording the user's surroundings by a camera and processing the camera image in order to incorporate additional information into the camera image. The additional information includes, for example, highlighting the connection point when the physical connection point of the component is visible in the camera image.

Furthermore, an acoustic output may also be provided, which includes, for example, the activation of a loudspeaker. The acoustic output may, for example, be a voice output through which the connection point designation is spoken.

Furthermore, it may be provided within the scope of the invention that, when initiating the output, at least one of the following steps is performed if the suitability of the installation element for installation in the installation environment is determined to be insufficient based on the result of the verification:
Initiating an output of a warning and/or error message, preferably the warning and/or error message that the installation element is not suitable for use in the installation environment and that a functionality of the installation element is significantly impaired;
Initiating a correction of the connection in the installation specification;
Initiating an output of an installation instruction and/or action recommendation, preferably with an indication of another installation element with a higher suitability than the verified installation element for installation in the installation environment.

This has the advantage of providing immediate and faster information to the user during installation if it is determined during the verification that the installation element is not suitable for the installation environment. It also allows the user to correct their activity more quickly or to be better able to recognize possible alternatives.

It may also be possible that the method comprises the following further step:
Automatic documentation of the suitability of the installation element depending on the result of the verification.

This has the advantage that easier traceability is guaranteed for subsequent checks. Furthermore, this significantly reduces the time required and the error rate of the input for the user, as manual documentation is no longer necessary.

Optionally, it may be provided that the method comprises the following further step:
Providing installation data of the installation element, in particular of a cable and/or plug connection, the installation data comprising planning data for properties of the installation element.

Furthermore, it may be provided that the method comprises the following further step:
Providing installation data of the installation environment, the installation data comprising planning data for properties of the installation environment.

This has the advantage that the method enables a simpler and error-free assignment of properties of an installation element to be installed and/or properties of an actual installation environment to the corresponding planning data and may thus significantly support a user during installation and simplify and accelerate the process. Furthermore, this enables potential problems to be identified more quickly using the planning data provided in order to avoid subsequent malfunctions in the operation of a machine.

A further advantage within the scope of the invention is achievable if the at least one feature of the installation element comprises at least one of the following:
a permissible temperature range for which the installation element is suitable;
a range of humidity for which the installation element is suitable;
a nominal electrical voltage for which the installation element is suitable;
a minimum bending radius for which the installation element is suitable;
a minimum and/or maximum mechanical load for which the installation element is suitable;
a permissible acceleration for which the installation element (10) is suitable;
a minimum and/or maximum number of wires within the plug connection and/or cable;
a coding of the plug connection as a signal line A-, B-, C-, D-, or X-coded and/or as a power line A-, K-, L and/or as a data line A-, B-, D-, X-, and Y-coded and/or with LED and/or coding as a shielded or unshielded plug connector and/or a hybrid line, in particular as a combination of the aforementioned lines;
a specific cable outlet, preferably a connector for a range of 0° to 90°, preferably 45° to 60°, for which the installation element is suitable;
a specific connection on the respective sides for which an installation element is suitable, in particular as an M8, M12, M23, RJ45, 7/8 (seven-eighths), MQ15, MSUD (valve connector), Deutschstecker or RJ45PP connection;
a specific connector type for which the installation element is suitable, in particular a connector type of the type socket-socket, socket-plug, plug-socket or plug-plug, H, T and Y pieces and distributors;
a specific application for which the installation element is suitable, in particular as an AS-Interface, Ethernet, motor, fieldbus application or sensor/actuator cable;
a corresponding design of the installation element depending on the environment for which the installation element is suitable;
a safety and/or redundancy requirement for which the installation element is suitable.

According to a further possibility, it may be provided that the at least one property of the installation environment comprises at least one of the following:
a temperature range which is intended as the air temperature in the installation environment;
a humidity level that is intended in the installation environment;
a wetness which is intended in the installation environment;
an electrical voltage which is intended as an operating voltage for the installation element;
a chemical resistance, which is intended in the installation environment;
an air pressure which is intended in the installation environment;
a UV exposure, which is intended in the installation environment;
a bacterial load, which is intended in the installation environment;
a biological load (e.g. animal substances etc.), which is intended in the installation environment;
a vibration, which is intended in the installation environment;
a noise load, i.e. ambient noise, which is intended in the installation environment;
a structure-borne sound, which is intended in the installation environment;
a corresponding design of the installation element depending on the application sector for which the installation element is suitable.

This makes it possible to ensure a more precise determination of a problem during installation. Furthermore, this has the advantage of ensuring a more effective action recommendation regarding a more suitable installation element or a more effective assessment of the suitability of the installation element despite deviation from a measured property.

It is also conceivable that verifying the suitability of the installation element for installation in the installation environment comprises the following steps:
Determining the at least one property of the installation element, preferably from a database and/or from a data memory, wherein the at least one property in each case defines a requirement for a parameter of the installation environment and/or specifies a technical parameter of the installation element;
Determining the at least one property of the installation environment, preferably by a measurement and/or from a database and/or from a data memory, wherein the at least one property in each case defines a requirement for the technical parameter of the installation element and/or indicates the parameter of the installation environment;
Performing the compatibility assessment by verifying the at least one requirement to determine the suitability of the installation element for installation in the installation environment as sufficient if satisfied and insufficient otherwise.

This makes it possible to ensure more accurate suitability verification during installation. Furthermore, this has the advantage of ensuring a more effective action recommendation regarding a more suitable installation element or a more effective assessment of the suitability of the installation element despite deviation from a measured property.

Is further conceivable within the scope of the invention that the method comprises the following further steps:
Receiving an identifier of the installation element, preferably from a reader, preferably by a scanner, to verify the suitability of the installation element for the installation environment;
Reading at least one property of the installation element from a database based on the identifier received.

This makes it possible to ensure easier, faster and error-free assignment of installation elements and their properties when verifying the suitability for the installation environment.

It may be envisaged within the scope of the invention that the method comprises the following further step when verifying the suitability:
Checking compliance with at least one reference and/or limit value for the at least one property of the installation element, in particular temperature and/or humidity and/or electrical voltage.

This has the advantage of ensuring that a verification result is provided more quickly. Furthermore, this enables a more efficient and targeted suitability verification with regard to individual properties to ensure a better and more concrete assessment and action recommendation.

It is further conceivable that the method comprises the following steps if a deviation of the at least one property of the installation element from the at least one reference and/or limit value is detected:
Simulating an effect of the deviation to determine the suitability of the installation element for installation in the installation environment depending on the effect;
Specifying another installation element that has a higher suitability for use in the installation environment and/or ensures a functionality of the machine if the suitability is determined to be insufficient; and
Generating an output of the installation information depending on a result of the simulation, preferably outputting a list of suitable installation elements for the installation environment.

This enables deviations to be checked in the form of suitable installation elements. This optimization may be achieved by simulating and outputting the effects of deviations. By simulating, it is advantageously possible to determine whether the specified installation element is an alternative that has a higher suitability for the installation environment. The simulation may also be used to determine whether the specified installation element is an alternative that fulfills all the required properties in the installation environment.

It is further conceivable within the scope of the invention that the method comprises the following steps if a deviation of the at least one property of the installation element from the at least one reference and/or limit value is detected:
Simulating a negative effect of the deviation in order to specify another installation element whose use neutralizes the negative effect;
Generating an output of the installation information depending on a result of the simulation, preferably outputting a list of suitable installation elements for the installation environment.

This makes it possible to check deviations in the form of suitable further installation elements. By simulating the negative effect, it is advantageously possible to determine whether the further specified installation element may eliminate the negative effect of the deviation during an installation.

Another object of the invention is an apparatus for data processing with means for carrying out the method according to one of the preceding claims. Thus, the apparatus according to the invention has the same advantages as those described in detail with reference to a method according to the invention. The apparatus may be part of at least or exactly one of the at least one machine.

Another object of the invention is a computer program, in particular a computer program product, comprising instructions which, when the computer program is executed by a computer, cause the computer to carry out the method according to the invention. Thus, the computer program according to the invention has the same advantages as those described in detail with reference to a method according to the invention.

The computer may be a data processing apparatus, for example the apparatus according to the invention, which executes the computer program. The computer may have at least one processor for executing the computer program. A non-volatile data memory may also be provided, in which the computer program is stored and from which the computer program may be read out by the processor for execution.

It is also conceivable that the computer comprises at least one integrated circuit such as a microprocessor or an application-specific integrated circuit (ASIC) or an application-specific standard product (ASSP) or a digital signal processor (DSP) or a field programmable gate array (FPGA) or the like. The computer may further comprise at least one interface for data exchange, e.g. an Ethernet interface or an interface for LAN (Local Area Network) or WLAN (Wireless Local Area Network) or System-on-a-Chip (SoC) or another radio interface such as Bluetooth or Near Field Communication (NFC). Furthermore, the computer may be designed as one or more control devices, i.e. also as a system of control devices. The computer may, for example, also be provided in a cloud and/or as a server in order to provide data processing for a local application via the interface. It is also possible for the computer to be designed as a mobile device, such as a smartphone.

Another object of the invention may be a computer-readable storage medium comprising the computer program according to the invention. The storage medium is designed, for example, as a data memory such as a hard disk and/or a non-volatile memory and/or a memory card. The storage medium may, for example, be integrated into the computer.

Furthermore, the method according to the invention may also be implemented as a computer-implemented method.

Further advantages, features and details of the invention are apparent from the following description, in which embodiments of the invention are described in detail with reference to the drawings. The features mentioned in the claims and in the description may be essential to the invention individually or in any combination.

### BRIEF DESCRIPTION OF THE DRAWINGS

For a better understanding of the disclosure, reference is made to the following drawings:

FIG. 1: A central connection in a machine by means of a control cabinet.

FIG. 2: A decentralized connection according to embodiments of the invention.

FIG. 3 A schematic representation of parts of a system according to embodiments of the invention.

FIG. 4 A schematic representation of details of a method according to embodiments of the invention.

FIG. 5 A schematic representation of steps of a method according to embodiments of the invention.

### DESCRIPTION OF THE EMBODIMENTS

Planning, installing and setting up machines and electronic automation technology is a complex task. This applies to centralized control cabinet systems as well as decentralized systems in which control modules are attached directly to the plants. The corresponding processes are carried out by different people, such as plant planners, electrical planners, installers, system programmers, etc. A special feature of decentralized systems is the distribution of modules at different points on a machine compared to centralized control cabinet systems. For larger machines in particular, simultaneous installation, i.e. installation carried out by several users at the same time, may be advantageous for time and logistical reasons. To enable a smooth installation process, the work status should be documented automatically, user-specifically and digitally in real time. For various reasons (e.g. maintenance planning, system diagnostics), it is important to have complete documentation of all relevant information throughout the entire plant life cycle, including documentation regarding the suitability of the installed components and/or parts.

During installation, it may happen that the actual situation on site deviates from the intended planning. This means that the originally planned components no longer match the actual environmental conditions. In such cases, a method and system that automatically compares the product properties with the environmental properties during installation and checks for compatibility may provide support. In the event of a lack of compatibility, a user is supported by generated and displayed notes or alternative suggestions from the system.

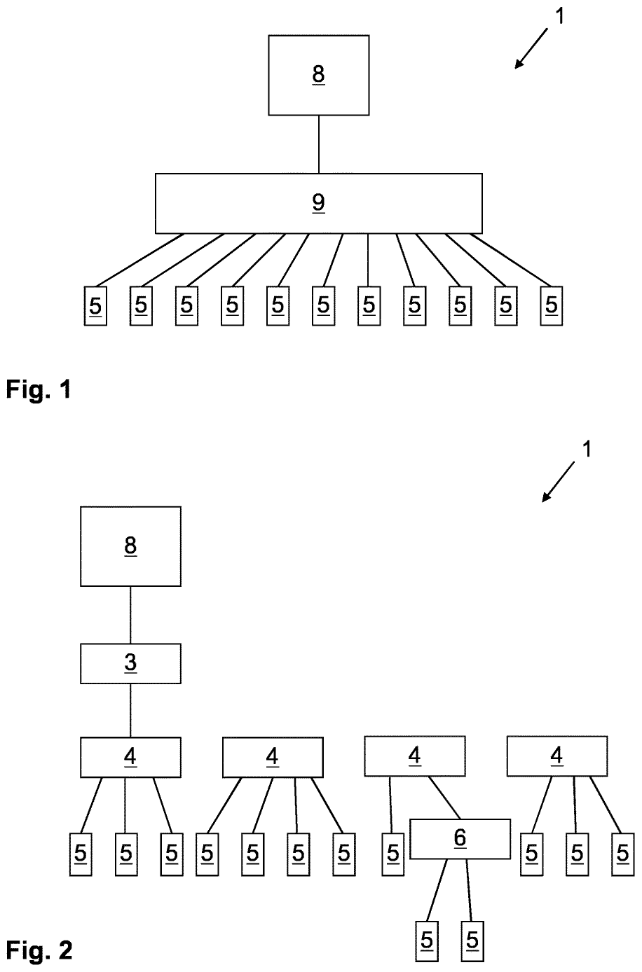

FIG. 1 schematically shows a centralized connection using a control cabinet 9 in order to contrast this with a decentralized connection using spatially decentralized electrical components 4 of a machine 1 in FIG. 2. Instead of connecting all devices 5 such as sensors and actuators directly to the control cabinet 9 as shown in FIG. 1, several components 4, in particular connection modules, may be used in the decentralized wiring in FIG. 2. Like the control cabinet 9, these enable the devices 5 to be coupled with a control device 8 such as a PLC. However, the connection modules 4 may be decentralized and distributed in the vicinity of the devices 5. The connection modules 4 thus only partially interconnect the devices 5, with the connection modules 4 together or, for example, one and/or more connection modules 4 each performing the entire interconnection via one and/or more hubs 6. In order to enable the configuration and/or control of the connection modules 4 centrally, a master module 3 may be connected upstream of several of the individual connection modules 4. It is also possible for the interconnection to be further subdivided by means of at least one hub 6.

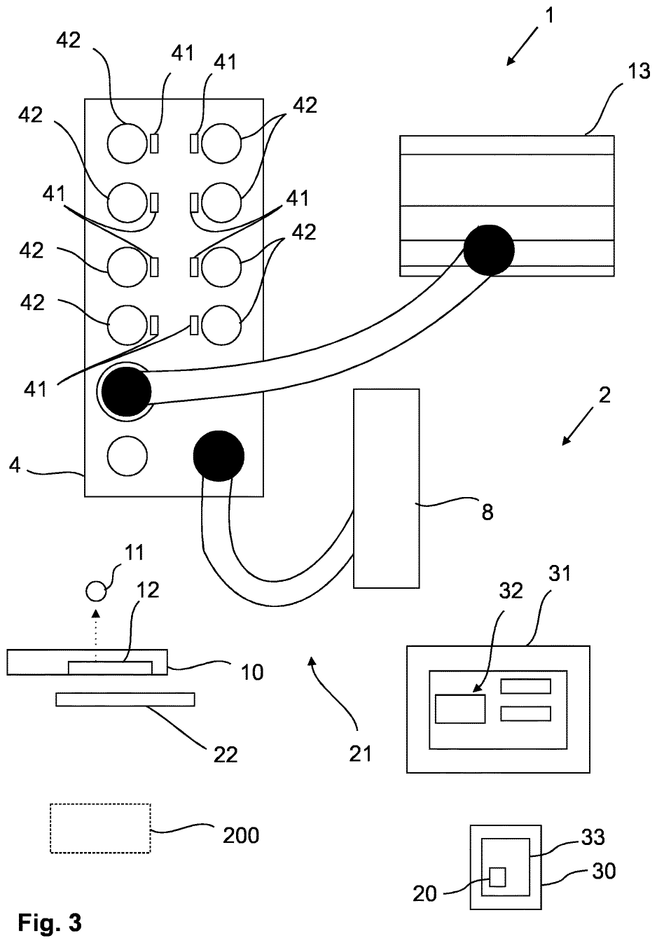

FIG. 3 shows parts of a system 2 according to embodiments of the invention, which may be provided for a computer-aided verification of an installation element for an installation environment during the installation of spatially decentralized electrical components 4 of a machine 1. The system 2 may comprise a detection device 22, in particular a scanner 22 or a camera 22, for providing an identifier 11 of an installation element 10, preferably a cable 10 or a component 10. Furthermore, the system 2 may comprise at least one electrical component 4, preferably in the form of a connection module 4 for connection to the installation element 10 and further installation elements 10. Likewise, a data processing apparatus 30 may be part of the system 2, wherein said data processing apparatus 30 may comprise means for carrying out the steps of a method 100 according to embodiments of the invention. The identifier 11 may be encoded in a machine-readable code 12 associated with the installation element 10, in particular arranged on the installation element 10, wherein the machine-readable code 12 is made machine-readable by means of the detection device 22. It is thus possible for a user to scan the code 12 by means of the detection device 22 and thus transmit the identifier 11 to the data processing apparatus 30.

Furthermore, the components 4 and at least one computer 30, 31 and/or a control device 8 may each be connected to one another via a bus system 21 for bidirectional communication, wherein the bidirectional communication may be provided based on a communication protocol for a field bus system, in particular based on a ProfiNet, Ethernet/IP or 802.3 standard, and/or the bidirectional communication may be provided in a wired manner via a bus system 21 or wirelessly by means of Bluetooth or WLAN, based on a standard according to IEEE 802.11 or based on a mobile radio telecommunications standard. In order to enable operation of the component 4, the component 4 may also be connected to a power supply 13.

Further shown is a computer program 20 comprising instructions which, when the program is executed by a computer 30, cause the computer 30 to perform the steps of the method 100 according to embodiments of the invention.

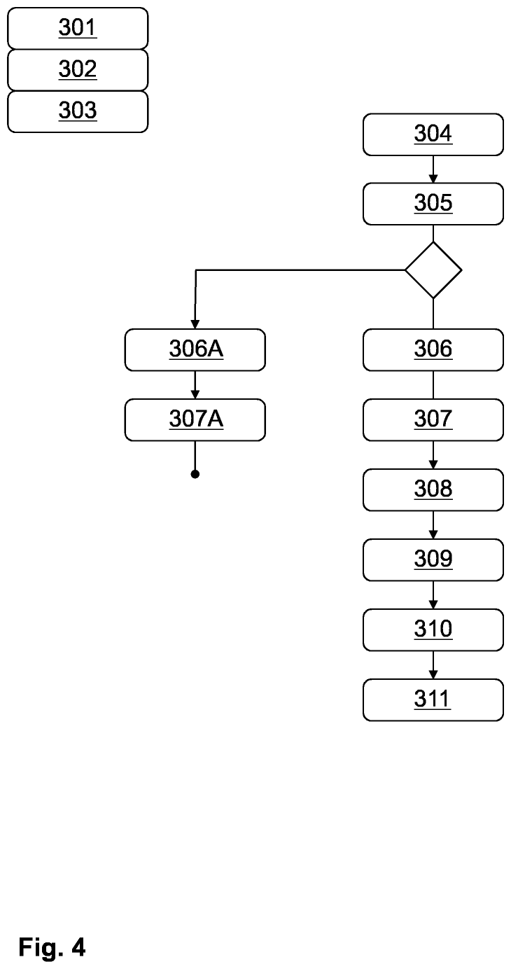

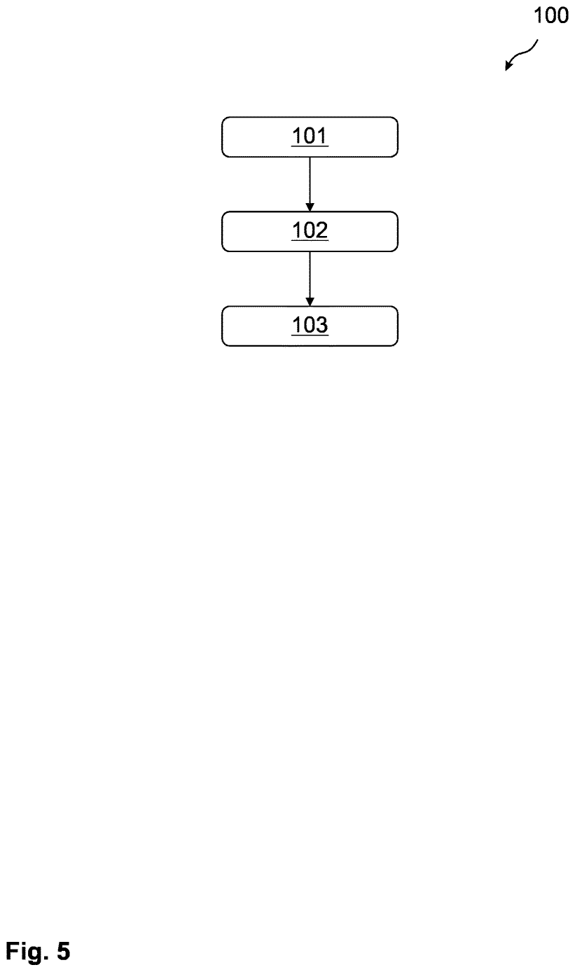

FIGS. 4 and 5 visualize method steps of the method 100, in which a computer-aided verification of an installation element, in particular a component and/or cable and/or plug connection, for an installation environment is carried out. According to a first method step 101 shown in FIG. 5, a verification of a suitability of the installation element for an installation in the installation environment may be provided, wherein this is preferably verified based on a compatibility assessment of at least one property of the installation element in relation to at least one property of the installation environment, in particular a temperature and/or humidity and/or electrical voltage and/or acceleration. Subsequently, according to a second method step 102, at least one installation information may be generated based on a result of the verification in the first method step to support a user during installation. Then, according to a third method step 103, an output of the generated at least one installation information for the user may be initiated.

By documenting the verification and installation, i.e. the installation documentation, at least one of the following pieces of information may be documented, for example: Work steps of the user with additional information on the work steps such as a processing time, which machine is being worked on, which user, for example which installer or fitter, carried out the activities and when, which component has been wired and/or cabled, has the installation step been completed, which port/connection point was used, do open cables exist and what are the properties of the open cable, e.g. length, environmental parameters, e.g. temperature, humidity, current project status, protection class, e.g. IP67. The user, especially the worker, may also enter the cause, reason or complaint in the event of deviations from the validated installation activities. The installation documentation may be stored in a database, for example. If necessary, a user may trigger the documentation with physical actions (keystroke, screen, double-click).

In FIG. 4, a method 100 according to embodiments of the invention is visualized with further details. Using a computer 31 shown in FIG. 3, such as a tablet or laptop, a user may first perform a user login 301. For this purpose, the user may use a graphical user interface 32, which is provided by the computer 31. A project selection 302 may also be made via the user interface 32, by which, for example, an installation specification 200 for a desired project is loaded. This allows a start 303 for verifying an installation element 10, in particular a component 10 and/or cable 10 and/or plug connection 10, for an installation environment.

When the installation element 10 or component 10, for example a cable 10, is installed in an installation environment, according to the method step 304, the component 10 is first identified by a reading device in preparation for verification and installation. For example, the identifier 11 may comprise an information relating to one or more technical properties of the cable including, for example, a length of the cable 10. The identifier 11 may be read or captured by the reading device by scanning, wherein the identifier 11 may for example be arranged as a machine-readable code or as a printed code on the cable 11. Optionally, this identification step may be performed repeatedly by the reading device during the method or at a time selected as suitable by the user in order to capture the identifier again.

According to method step 305, the verification is then carried out, for example, based on a comparison of the product and/or material properties of the cable 10 with the environmental conditions with regard to compatibility. In other words, the product properties are used to verify whether the cable 10 used (actual component) corresponds to the planned cable (target component). The measured environmental conditions are used to verify whether the installation environment (actual environment) corresponds to the planned environment (target environment), i.e. whether the properties of the installation environment correspond to the properties of the planned environment. In other words, a verification is made for compatibility or a lack of compatibility between component 10 and the installation environment.

If the component and the environmental conditions match the plans, an installation information is generated according to method step 306a, for example as a confirmation of the suitability of the component 10, and the output of the information is initiated according to method step 307a.

In the event of a mismatch of a property, either a warning and/or an error message is generated according to method step 306 and then the output is initiated according to step 307. Or optionally, in the case of a non-match according to step 306, a search for possible alternative components for a component 10 that might be more suitable for the actual installation environment may also be initiated. This option is generated as an indication in step 306 and the output to the user is initiated in step 307. Optionally, in the case of a non-match according to method step 306, an installation instruction or an action recommendation may also be generated and the output initiated in step 307.

When determining a deviation between the target and actual values during the verification, planning data with stored product properties and/or planning data with stored environmental properties may optionally be accessed in accordance with method step 308. Subsequently, in method step 309, the product properties and specifications of the component 10 may be compared with the specifications of the intended component stored in the planning documents.

In other words, in the verification according to method step 305, it may be determined as a result that if the actual component corresponds to the target component and the actual environment corresponds to the target environment, then there is no deviation from the planning documents to the actual situation and therefore a confirmation of suitability is optionally output to the user. However, if, for example, the actual component corresponds to the target component but the actual environment differs from the target environment, this information is generated as installation information in the form of a warning in step 306a and initiated as an output in step 307a, comprising that the actual environment differs from the planned environment.

When a deviation is detected such that a reference or limit value of a property of a component or of the environment is exceeded or not reached, a simulation according to method step 310 is optionally carried out to determine an effect of the exceeding or falling below of the at least one reference or limit value due to the deviation in the properties of the environment from the planned situation. In the simulation, one result may be that the functional capacity of the component is not or not significantly affected. Therefore, the scheduled component is suitable for use in the non-scheduled installation environment. Or the simulation may show that the functional capacity of the component is significantly impaired. In this case, the output result shows that the scheduled component is not suitable for use in the non-scheduled environment. In both cases, the respective result is generated and output as a warning message. This informs the user that the scheduled component is not suitable for use in the non-scheduled environment and that its functionality is significantly impaired.

In the simulation, for example, the requirements of the actually measured environmental properties are optionally combined with the properties of the planned component in an analysis in order to create a requirements profile for a suitable component. This requirement profile is then used, for example, as a minimum requirement for suitable components, so that all components stored in the database may be analyzed for the best possible match with the minimum required properties. The verification is carried out by comparing the product information, for example by connecting to a product data management system or a product life cycle management system, which may also enable automated or manual reading and input of data.

Optionally, a search for suitable alternative components that are suitable for use in the non-scheduled environment and ensure the functionality of the machine may be carried out in accordance with method step 311. This is followed, for example, by an automatic comparison with all components stored in a database for the best possible match between the component specifications and the specifications of the scheduled component. It is specified that a suitable alternative is a component, which differs in the at least one property with regard to which the scheduled component is not suitable for use in the non-scheduled environment, insofar as the functionally relevant limit values are complied with.

The search according to step 311 may additionally reveal that either none of the components 10 that may be available at an installation location, for example, guarantee the minimum requirements of the non-scheduled environmental properties, or at least one suitable component 10 is available in another warehouse for the installation. In the latter case, for example, a list of suitable alternatives is generated and the list selection is initiated as an output to the user. Optionally, a material order may also be placed according to the user's choice.

In another case, the result of the search may be that none of the available components and none of the components in stock in a warehouse meet the minimum requirements of the non-scheduled environmental properties according to the simulation. Then, for example, a message is generated and displayed to the user that there is no more suitable component than the planned one.

Furthermore, the search may also reveal that one of the available components 10 fulfills the minimum requirements of the non-scheduled environmental properties and is therefore suitable as an alternative for the scheduled component. Such a result may then be generated as installation information that includes the alternative component as an installation recommendation. The recommendation may then be output to the user.

Although some aspects have been described in connection with an apparatus, it is clear that these aspects also constitute a description of the corresponding method, wherein an element or apparatus corresponds to a method step or a feature of a method step. Similarly, aspects described in connection with a method step also constitute a description of a corresponding block or element or feature of a corresponding apparatus.

Embodiments of the invention may be implemented on a computer system. The computer system may be a local computing device (e.g., personal computer, laptop computer, tablet computer, or cell phone) having one or more processors and one or more storage devices, or a distributed computing system (e.g., a cloud computing system having one or more processors and one or more storage devices distributed at various locations, such as at a local client and/or one or more remote server farms and/or data centers). The computer system may comprise any circuitry or combination of circuitry. In one embodiment, the computer system may comprise one or more processors of any type. As used herein, the term “processor” may refer to any type of computing circuit, such as a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), a multicore processor, a field programmable gate array (FPGA), or any other type of processor or processing circuit. Other types of circuitry that may be included in the computer system may be a customer specific circuit, an application specific integrated circuit (ASIC), or the like, such as one or more circuits (e.g., a communication circuit) for use in wireless devices such as cell phones, tablet computers, laptop computers, two-way radios, and similar electronic systems. The computer system may include one or more storage devices, which may include one or more storage elements suitable for the particular application, such as a main memory in the form of a random access memory (RAM), one or more hard disks, and/or one or more drives that handle removable media such as compact disks (CD), flash memory cards, digital video disks (DVD), and the like. The computer system may also include a display device, one or more speakers, and a keyboard and/or control device, which may include a mouse, trackball, touch screen, voice recognition device, or other device that allows a system user to input information to and receive information from the computer system.

Some or all of the method steps may be performed by (or using) a hardware device, such as a processor, a microprocessor, a programmable computer, or an electronic circuit. In some embodiments, some or more of the key method steps may be performed by such a device.

Depending on specific implementation requirements, embodiments of the invention may be implemented in hardware or in software. The implementation may be using a non-transferable storage medium such as a digital storage medium, for example a floppy disk, a DVD, a Blu-Ray, a CD, a ROM, a PROM, an EPROM, an EEPROM or a FLASH memory, on which electronically readable control signals are stored, which interact (or may interact) with a programmable computer system so that the respective method is performed. Therefore, the digital storage medium may be computer readable.

Some embodiments of the invention comprise a data carrier having electronically readable control signals capable of interfacing with a programmable computer system so as to perform any of the methods described herein.

In general, embodiments of the present invention may be implemented as a computer program product comprising a program code, wherein the program code is for performing one of the methods when the computer program product is running on a computer. For example, the program code may be stored on a machine-readable medium.

Other embodiments comprise the computer program for performing any of the methods described herein stored on a machine-readable medium.

In other words, therefore, one embodiment of the present invention is a computer program comprising a program code for performing one of the methods described herein when the computer program is running on a computer.

Thus, another embodiment of the present invention is a storage medium (or a data carrier or computer readable medium) on which the computer program for performing one of the methods described herein is stored when executed by a processor. The storage medium, digital storage medium or recorded medium is typically tangible and/or non-transferable. Another embodiment of the present invention is an apparatus as described herein including a processor and the storage medium.

Thus, another embodiment of the invention is a data stream or sequence of signals representing the computer program for performing one of the methods described herein. The data stream or sequence of signals may, for example, be designed such that it may be transmitted via a data communication link, for example via the Internet.

Another embodiment comprises a processing means, such as a computer or programmable logic device, configured or modified to perform any of the methods described herein.

Another embodiment comprises a computer on which the computer program for performing one of the methods described herein is installed.

Another embodiment of the invention comprises a device or system configured to transmit (e.g., electronically or optically) a computer program to a receiver for performing any of the methods described herein. The receiver may be, for example, a computer, a mobile device, a storage device, or the like. The device or system may include, for example, a file server for transmitting the computer program to the receiver.

In some embodiments, a programmable logic device (e.g., a field programmable gate array) may be used to perform some or all of the functions of the methods described herein. In some embodiments, a field programmable gate array may cooperate with a microprocessor to perform any of the methods described herein. In general, the methods are preferably performed by any hardware device.

### LIST OF REFERENCE SIGNS

1 Machine, plant
2 System
3 Master module
4 Module, switch, component, connection module
5 Devices, sensor, actuator
6 Hub
8 Control device, PLC
9 Control cabinet
10 Installation element
11 Identifier
12 Means for identification, machine-readable code
13 Power supply
20 Computer program
21 Bus system
22 Detection device
30 Apparatus
31 Computer
32 User interface
33 Data memory
41 Display element
42 Connection point, slot
100 Method
101 First method step
102 Second method step
103 Third method step
200 Installation specification
301 User login
302 Project selection
303 Instructions start
304 Identification
305 Verification
306 Generation
307 Initiating an output
308 Accessing stored data
309 Adjust properties
310 Simulation
311 Search

1. A method for a computer-aided verification of an installation element for an installation environment, the method comprising the following steps:
Verifying a suitability of the installation element for an installation in the installation environment;
Generating at least one installation information based on a result of the verification to assist a user in the installation; and
Initiating an output of the generated at least one installation information for the user.

2. The method according to claim 1, wherein the at least one installation information comprises an installation instruction for assisting the user with the installation.

3. The method according to claim 1, wherein upon initiating the output, at least one of the following steps is performed when, based on the result of the verification, the suitability of the installation element for the installation in the installation environment is determined to be insufficient:
Initiating an output of a warning and/or error message; Initiating a correction of the connection in the installation specification;
Initiating an output of an installation instruction and/or an action recommendation.

4. The method according to claim 1, wherein the method comprises the following further step:
Automatic documentation of the suitability of the installation element depending on the result of the verification.

5. The method according to claim 1, wherein the method comprises the following further step:
Providing installation data of the installation element, the installation data comprising planning data for the at least one property of the installation element.

6. The method according to claim 1, wherein the method comprises the following further step:
Providing installation data of the installation environment, wherein the installation data comprises planning data for the at least one property of the installation environment.

7. The method according to claim 1, wherein the at least one property of the installation element comprises at least one of the following:
a permissible temperature range for which the installation element is suitable;
a range of humidity for which the installation element is suitable;
a nominal electrical voltage for which the installation element is suitable;
a permissible acceleration for which the installation element is suitable;
a minimum bending radius for which the installation element is suitable;
a minimum and/or maximum mechanical load for which the installation element is suitable;
a minimum and/or maximum number of wires within the plug connection and/or cable;
a coding of the plug connection as a signal line A-, B-, C-, D-, or X-coded and/or as a power line A-, K-, L and/or as a data line A-, B-, D-, X-, and Y-coded and/or with LED and/or coding as a shielded or unshielded plug connector and/or a hybrid line;
a specific cable outlet, for which the installation element is suitable;
a specific connection on the respective sides for which an installation element is suitable;
a specific connector type for which the installation element is suitable;
a specific application for which the installation element is suitable;
a corresponding design of the installation element depending on the environment for which the installation element is suitable;
a safety and/or redundancy requirement for which the installation element is suitable.

8. The method according to claim 1, wherein the at least one property of the installation environment comprises at least one of the following:
a temperature range, which is intended as the air temperature in the installation environment;
a humidity level that is intended in the installation environment;
a wetness which is intended in the installation environment;
an electrical voltage which is intended as an operating voltage for the installation element;
a chemical resistance, which is intended in the installation environment;
an air pressure which is intended in the installation environment;
a UV exposure, which is intended in the installation environment;
a bacterial load, which is intended in the installation environment;
a biological load which is intended in the installation environment;
a permissible acceleration for which the installation element is suitable;
a vibration, which is intended in the installation environment;
a noise load which is intended in the installation environment;
a structure-borne sound, which is intended in the installation environment;
a corresponding design of the installation element depending on the application sector for which the installation element is suitable.

9. The method according to claim 1, wherein verifying the suitability of the installation element for installation in the installation environment comprises the following steps:
Determining the at least one property of the installation element wherein the at least one property in each case defines a requirement for a parameter of the installation environment and/or specifies a technical parameter of the installation element;
Determining the at least one property of the installation environment wherein the at least one property in each case defines a requirement for the technical parameter of the installation element and/or indicates the parameter of the installation environment;
Performing the compatibility assessment by verifying the at least one requirement to determine the suitability of the installation element for installation in the installation environment as sufficient if satisfied and insufficient otherwise.

10. The method according to claim 1, wherein the method comprises the following further steps:
Receiving an identifier of the installation element to verify the suitability of the installation element for the installation environment;
Reading at least one property of the installation element from a database based on the identifier received.

11. The method according to claim 1, wherein the method comprises the following further step when verifying the suitability:
Checking compliance with at least one reference and/or limit value for the at least one property of the installation element,

12. The method according to claim 11, wherein the following steps are performed when a deviation of the at least one property of the installation element from the at least one reference and/or limit value is detected:
Simulating an effect of the deviation to determine the suitability of the installation element for installation in the installation environment, depending on the effect;
Specifying a further installation element having a higher suitability for use in the installation environment and/or ensuring a functionality of the machine if the suitability is determined to be insufficient; and
Generating an output of the installation information depending on a result of the simulation.

13. The method according to claim 11, wherein the following steps are performed when a deviation of the at least one property of the installation element from the at least one reference and/or limit value is detected:
Simulating a negative effect of the deviation in order to specify a further installation element, the use of which neutralizes the negative effect;
Generating an output of the installation information depending on a result of the simulation.

14. A data processing apparatus comprising:
one or more processors;
a non-transitory computer readable medium storing a computer program comprising instructions, which, when executed by the one or more processors, cause the one or more processors to:
Verify a suitability of the installation element for an installation in the installation environment;
Generate at least one installation information based on a result of the verification to assist a user in the installation; and
Initiate an output of the generated at least one installation information for the user.

15. A non-transitory computer readable medium storing a computer program comprising instructions, which, when the computer program is executed by a computer, cause the computer to:
Verify a suitability of the installation element for an installation in the installation environment;
Generate at least one installation information based on a result of the verification to assist a user in the installation; and
Initiate an output of the generated at least one installation information for the user.

16. The method of claim 1, wherein at least one of:
(a) wherein the verification of suitability of the installation element for an installation in the installation environment is based on a compatibility assessment of at least one property of the installation element in relation to at least one property of the installation environment;
(b) wherein the at least one property of the installation element in relation to at least one property of the installation environment comprises a temperature and/or humidity and/or electrical voltage and/or acceleration; and/or
(c) wherein initiating the output comprises at least one of the following steps:
Initiating an output of the installation instruction as an indication of a connection point of an electrical component for a connection of the installation element and/or an indication of suitability of the installation element;
Initiating a visual output of the installation instruction; or
Initiating an acoustic output, of the installation instruction;

17. The method of claim 3, wherein at least one of:
wherein the warning and/or the error message comprises that the installation element is not suitable for use in the installation environment and a functionality of the installation element is significantly impaired; and/or wherein the installation instruction and/or an action recommendation comprises an indication of another installation element with a higher suitability than the verified installation element for installation in the installation environment

18. The method of claim 5, wherein the installation element comprises a cable and/or plug connection.

19. The method of claim 12, wherein the output of the installation information comprises a list of suitable installation elements for the installation environment.

20. The method of claim 13, wherein the output of the installation information comprises a list of suitable installation elements for the installation environment.
